(19) United States
(12) Patent Application Publication
(10) Pub. No.: US 2009/0166880 A1
(43) Pub. Date: Jul. 2, 2009

(54) ELECTRICAL BONDING PAD

(75) Inventors: Laurent Chabert, Saint Martin D'Heres (FR); Sebastien Pruvost, Froges (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS S.A., Montrouge (FR)

(21) Appl. No.: 12/344,035

(22) Filed: Dec. 24, 2008

(30) Foreign Application Priority Data
Dec. 28, 2007 (FR) 07 60446

(51) Int. Cl. H01L 23/488; H01L 21/768

(52) U.S. Cl. 257/773; 438/612; 257/E23.023; 257/E21.59

(57) ABSTRACT

An electrical bonding pad for an integrated circuit, comprising an encapsulation layer for receiving electrical signals and for covering a portion of a stack of conductive layers. The pad further comprises a conductive area in the stack, with the conductive area being at least partially covered by the encapsulation layer. The conductive area is intended for the passage of electrical signals received by the encapsulation layer and traveling towards a circuit core, and is electrically insulated from the encapsulation layer in a manner that at least partially decouples the electrical signals received from the encapsulation layer.

### BACKGROUND

1. Technical Field

The invention relates to an electrical bonding pad. It has applications particularly in integrated circuits, and more particularly in System On Chip (SOC) circuits.

2. Description of the Related Art

FIG. 1 shows an example of a bonding pad 1 for an integrated circuit comprising a stack 5 of metallization layers M1, . . . , M6. As is well known, each metallization layer includes metal areas, such as conductive tracks and conductive vias, surrounded by dielectric areas.

The pad 1 comprises an encapsulation layer 2 for receiving a radiofrequency signal, and a conductive output area 40 for delivering this radiofrequency signal to a circuit represented by the reference 400 and called the circuit core, situated laterally relative to the pad 1.

The encapsulation layer 2 may, for example, comprise an AluCap™ layer of aluminum. A contact layer 3, also of aluminum, ensures an electrical contact between the encapsulation layer 2 and the conductive output area 40.

The encapsulation layer 2 is intended to be soldered to a connecting wire, for example a gold wire, not represented.

The layers 2 and 3 sit on the stack 5 of metallization layers M1, M2 . . . , M6, with the last metallization layer M6 comprising the conductive area 40. The first metallization layer M1 sits on a silicon substrate 6.

The circuit core 400, for example rapid access memory, a CPU (central processing unit), a LNA (low noise amplifier), etc., is connected to a lateral end of the output layer 40 via conditioning means represented by the reference 300, for example a decoupling capacitor such as a 3D capacitor, and/or a device for converting the impedance and filtering the frequency.

This conditioning means 300 allow preparing the radiofrequency signal received from the gold wire so that it may be used by the circuit core.

It may be desirable to reduce the overall dimensions of the conditioning means.

### BRIEF SUMMARY

According to one embodiment, a bonding pad for an integrated circuit is provided, said pad comprising an encapsulation layer for receiving electrical signals, said encapsulation layer covering at least a portion of a stack of conductive layers. The pad further comprises at least one conductive area inside the stack, this conductive area being at least partially covered by the encapsulation layer. This conductive area is intended for the passage towards a circuit core of electrical signals received by the encapsulation layer. At least one conductive area is arranged inside the pad in a manner that it at least partially ensures the conditioning of the signals received by the pad. For example, at least one conductive area of the pad is electrically insulated from the encapsulation layer so as to at least partially decouple the electrical signals received from the encapsulation layer.

Therefore this bonding pad at least partially integrates a decoupling means, which allows reducing the space requirements for the decoupling of the signals received.

Therefore the pad has one or more conductive areas, for example vias, lines, etc., situated in the portion of the stack covered by the encapsulation layer. This or these area(s) are called “conductive areas of the pad” in the present description. The stack of metallic layers may of course comprise other conductive areas, external to the pad. These other conductive areas, for example vias, lines, etc., are common in stacks of metallic layers and are considered here as not being part of the pad when these other areas are not at least partially covered by the encapsulation layer.

There may be one or more conductive areas at least partially inside the portion of the stack corresponding to the pad. When there are several conductive areas, some of these conductive areas may be in electrical contact with the encapsulation layer.

There may be one or more conductive area(s) only partially covered by the encapsulation layer, but advantageously the conductive area or areas of the pad are completely inside the portion of the stack covered by the encapsulation layer, which thus limits the space requirements for the decoupling of the signals.

Advantageously, at least one of the conductive layers comprises a plurality of conductive areas at least partially covered by the encapsulation layer. These areas are insulated from each other by at least one insulating area which is at least partially covered by the encapsulation area.

Thus, in one embodiment, for a same conductive layer there are at least two conductive areas inside the portion of the stack corresponding to the pad, separated by at least one insulating area. The capacitance generated by this or these insulating areas between the conductive areas contributes to the decoupling of the electrical signals, and in a relatively compact manner.

Advantageously, the conductive areas of this plurality of conductive areas in the same conductive layer comprise two conductive areas separated by the insulating area and arranged such that one of the conductive areas surrounds the other.

This arrangement of two or more conductive areas allows obtaining facing surface areas which are relatively extensive, and therefore a relatively high decoupling capacitance.

Of course, it may be arranged such that each of the conductive layers comprises at most one conductive area for the portion of the stack corresponding to the pad. At least one conductive area is electrically insulated from the encapsulation layer in a manner that at least partially decouples the electrical signals received. The decoupling may be assured by a an insulating area in the portion corresponding to the pad.

For a conductive layer comprising two or more conductive areas, the invention is not limited by the configuration in which one of these areas surrounds the other.

For example, each of these two areas may have the shape of a rectangular flagstone, with the areas simply placed one atop the other in the conductive layer. The insulating space between these conductive areas allows at least partially decoupling the signals traveling through these areas.

In another example, these two areas may have the shape of two combs with interlaced teeth.

Advantageously, the pad comprises a set of conductive layers each comprising a plurality of conductive areas which are at least partially covered by the encapsulation layer. This increases the value of the decoupling capacitance.

Advantageously, for at least one layer in the set of conductive layers, each conductive area of this layer surrounds or is surrounded by another conductive area.

Therefore the invention is in no way limited by the configuration of the conductive area or areas of the pad inside the portion of the stack of conductive layers.

Advantageously, inside the portion corresponding to the pad, the conductive layer furthest from the encapsulation layer and into which a conductive area at least partially extends, additionally comprises an insulating area. In this manner the parasitic capacitance between this conductive layer comprising a conductive area closest to a substrate and said substrate is weaker than if this conductive layer were, for the portion contained in the pad, substantially constituted of only a conductive area.

Alternatively the conductive layer furthest from the input area and into which a conductive area at least partially extends, may comprise no insulating areas in the portion of said layer which corresponds to the pad.

Another embodiment proposes an integrated circuit, for example a motherboard or other circuit, where this circuit comprises a circuit core, for example rapid access memory, a CPU, a LNA, etc., as well as a bonding pad as described herein.

One embodiment is a method for manufacturing a bonding pad for an integrated circuit. The method comprises a step of creating a conductive area in a stack of conductive layers, and a step of creating an encapsulation layer at least partially covering the conductive area. The encapsulation layer is separated from the conductive area by an insulating area, in a manner that at least partially ensures a decoupling of electrical signals received by the encapsulation layer and traveling through the conductive area for delivery to a circuit core.

This process allows obtaining a bonding pad according to one embodiment.

The step of creating a conductive area in a stack of conductive layers may comprise conductive layer deposition steps, with at least one intervening step of forming a conductive area in one of these layers. The invention is in no way limited by the manufacturing techniques involved, which may include damascene, dual damascene, chemical mechanical polishing, RIE (reactive ion etching), etc.

One embodiment is an electrical bonding pad for an integrated circuit is provided, this pad comprising an encapsulation layer for receiving electrical signals and said layer covering at least a portion of a stack of conductive layers. The pad further comprises at least one conductive area in the stack, with this conductive area or areas being at least partially covered by the encapsulation layer. This or these conductive areas comprise (or each comprise) an area input and an area output for the passage towards a circuit core of electrical signals received by the encapsulation layer. At least one of this or these conductive area(s) is elongated between the area input and the area output in a manner that ensures frequency filtering of the electrical signals traveling through this at least one conductive area.

Thus the frequency filtering is at least partially performed inside the pad itself, which reduces the overall dimensions.

The width of the elongated conductive area may be chosen so that it at least partially ensures impedance matching.

The elongated conductive area may thus have the shape of a ribbon that has a certain thickness.

The elongated conductive area may extend in a manner that forms a spiral of more than a quarter turn, and preferably at least ⅜ of a turn, which allows conciliating the length of the elongated conductive area and its confinement within the portion of the stack covered by the encapsulation layer. The length of the elongated conductive area in fact determines the range of frequencies filtered by this conductive area. For certain applications, it may be desirable, depending on the frequency desired, for the elongated conductive area to have a length greater than the dimensions of the pad. The winding of the conductive area inside the pad allows a relatively wide choice of frequencies without requiring a pad of larger dimensions.

In particular, the elongated conductive area may extend to form a spiral of a plurality of turns, in a plurality of respective layers. The elongated conductive area may thus comprise one or more vias for passing from one layer to another. The conductive area may then act as an inductor.

The elongated conductive area may extend beyond the area output, to a virtual ground for example, while remaining at least mostly confined to the interior of the stack portion corresponding to the pad. In this manner the pad may integrate a transformer.

There may also be a supplemental elongated conductive area, insulated from the elongated area in a manner that forms a balun (BALanced-UNbalanced) for balancing the signal received. For example, a pad may comprise two elongated conductive areas separated from each other. One of these two elongated areas may comprise the area input and area output, while the other of these elongated areas may comprise a supplemental area output and a virtual ground.

There may also be more than two elongated conductive areas.

Of course, the elongated conductive area may extend between the area input and the area output in a single direction, in a manner that assumes the shape of a rod.

According to a further aspect of the invention, an integrated circuit is provided, for example a motherboard or other circuit, this circuit comprising a circuit core, for example rapid access memory, a CPU, a LNA, etc., as well as bonding pads as described herein.

One embodiment is a method for manufacturing a bonding pad for an integrated circuit. The method comprises a step of creating a conductive area in a stack of conductive layers, with this conductive area comprising an area input and an area output for the passage, towards a circuit core, of signals received by the pad. The created conductive area is elongated between the area input and the area output in a manner that ensures frequency filtering of the electrical signals traveling through this conductive area. An encapsulation layer for receiving and sending the electrical signals to the conductive area is also created, with said encapsulation layer at least partially covering the conductive area.

This method allows obtaining a pad which integrates a frequency filter for the signals received.

Other features and advantages will become clear in the description which follows.

### BRIEF DESCRIPTION OF THE SEVERAL VIEWS OF THE DRAWINGS

FIG. 1 schematically shows an example of a prior art bonding pad.

FIG. 2 schematically shows an example of a bonding pad according to an embodiment of the invention.

FIG. 3 is a top-down view of part of an example of a bonding pad according to the embodiment in FIG. 2.

FIG. 4 is a graph representing losses as a function of the frequency, for a prior art bonding pad and conditioning means, and for a bonding pad according to the embodiment in FIG. 2.

FIG. 5 schematically shows an example of a bonding pad according to another embodiment of the invention.

FIG. 6 is a top-down view of a conductive layer in an example of a pad according to an embodiment of the invention, for example the layer M6 or M4.

FIG. 7 schematically shows an example of a bonding pad according to an embodiment of the invention.

FIG. 8 is a perspective view of a conductive area of the bonding pad of FIG. 7. The rest of the pad is not represented in this figure.

FIG. 9 is a perspective view of a conductive area of a bonding pad according to an embodiment of the invention. The rest of the pad is not represented in this figure.

FIG. 10 schematically shows an example of a bonding pad integrating a balun according to an embodiment of the invention.

FIG. 11 is a perspective view of two conductive areas of the bonding pad of FIG. 10. The rest of the pad is not represented in this figure.

FIG. 12 schematically shows an example of a bonding pad according to an embodiment of the invention.

FIG. 13 is a perspective view of two conductive areas of the bonding pad of FIG. 12. The rest of the pad is not represented in this figure.

### DETAILED DESCRIPTION

The same reference numbers are used for similar objects.

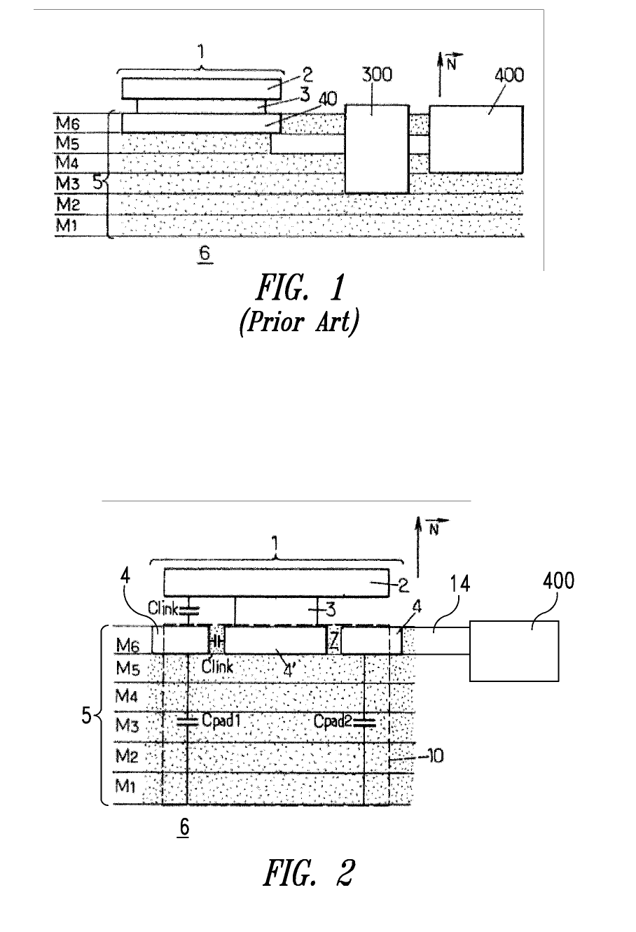

For reasons of clarity, the dimensions of the various elements represented in these figures are not in proportion to their actual dimensions. The dimensions and proportions represented may even vary from one figure to the next for the same reasons of clarity. A substrate 6 is positioned in the lower part of FIGS. 1, 2, 5, 7, 10, and 12, and N indicates a direction perpendicular to the surface of the substrate, pointing towards the top of the figures. The direction of the vector N is said to be vertical, and the directions normal to this vector are said to be horizontal. The terms “on”, “covering”, “under”, “below” and “above”, “on top of”, “underneath”, “lateral”, etc., are used with respect to the orientation of the vector N. By “on” or “covering”, it is understood that this means both “directly on” or “directly covering” as well as “indirectly on” or “indirectly covering”, meaning that a layer deposited “on” another may be separated from said other layer by at least one third layer, and that an area covered by a layer may be separated from this layer by other areas.

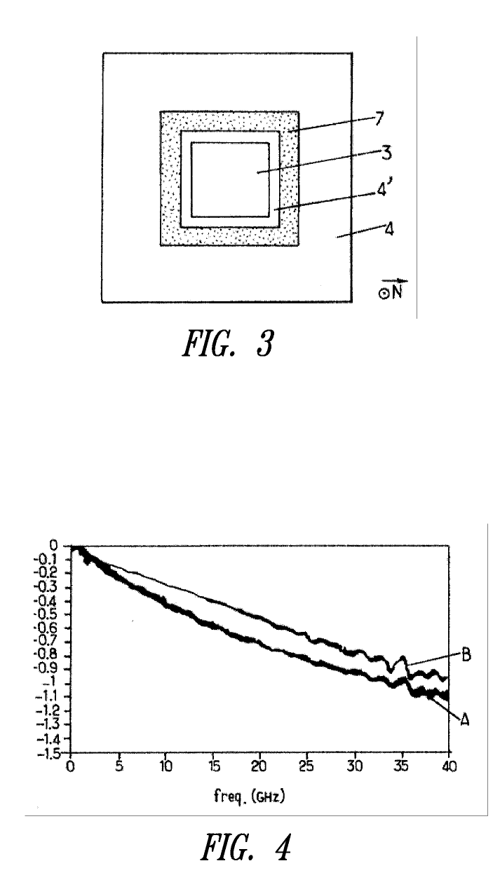

FIGS. 2 and 3 illustrate the same embodiment and will be discussed together. An electrical bonding pad 1 realized in a stack 5 of conductive layers M1, . . . , M6 comprises an encapsulation layer 2, for example a layer of AluCap™ realized in aluminum. This encapsulation layer 2 covers a portion 10, delimited by dotted lines in FIG. 2, of the stack 5 of conductive layers M1, . . . , M6.

The conductive layers M1, . . . , M6 are typically realized of metal areas surrounded by a dielectric material, for example silicon dioxide (SiO₂), silicon nitride (Si₃N₄), SiOC, SiOCH, FSG (fluorine doped silicate glass), PSG (phosphosilicate glass), BPSG (borophosphosilicate glass), porous materials, a combination of dielectric materials in successive layers, a mixture of dielectric materials, etc. The metal areas, typically vias, lines, or conductive areas, are formed in the dielectric material, for example by a simple damascene process.

The conductive areas may, for example, be realized of copper, aluminum, or another material.

The pad thus comprises two conductive areas 4, 4′ inside the same conductive layer M6. The area 4 surrounds the area 4′, and these areas 4, 4′ are separated from each other by an insulating area 7.

The encapsulation layer 2 is in electrical contact with the area 4′ via the contact layer 3.

The area 4 is used to deliver, to a circuit core 400 via a conductive connector 14, the signals received by the encapsulation layer. This area 4, mostly confined within the stack portion 10, is electrically insulated from the encapsulation layer 2. Due to the electrical insulation from the encapsulation layer 3, the signals received by the layer 4 are at least partially decoupled. In FIG. 2 the equivalent capacitances obtained through this particular arrangement are represented.

A first capacitance Cₗᵢₙₖ is obtained due to the absence of a contact layer between the area 4 and the encapsulation layer 2. A second capacitance Cₗᵢₙₖ′ is obtained in the layer M6, due to the insulation area 7 between the areas 4, 4′. As area 4 surrounds area 4′, the surface areas of the facing surfaces are relatively high, such that the value of the second capacitance Cₗᵢₙₖ′ may be relatively high. The decoupling may thus be assured inside the pad 1 itself, due to the decoupling capacitances Cₗᵢₙₖ, Cₗᵢₙₖ′.

The capacitances C_{pad1}, C_{pad2} represent the parasitic capacitances between the conductive areas 4, 4′ and the substrate 6. In the prior art, the conductive area (labeled 40 in FIG. 1) substantially occupies the entire portion of this layer which corresponds to the pad, so the parasitic capacitance thus generated may be relatively high. The pad represented in FIG. 2 is arranged such that the conductive layer closest to the substrate 6 and comprising conductive areas 4, 4′ also comprises an insulating area 7. Thus, the capacitance equivalent to the capacitances C_{pad1}, C_{pad2} is relatively low, particularly for applications at relatively high frequencies, for example those exceeding 20 GHz.

In addition, due to the presence of an insulating area 7 in the layer M6, the electrical field between this layer M6 and the substrate 6 is better distributed than in the prior art.

FIG. 4 is a graph representing losses as a function of the frequency, for a prior art bonding pad and conditioning means (curve A), and for a bonding pad according to the embodiment of FIG. 2 (curve B). The frequencies on the x axis are in gigahertz, and the losses on the y axis are in decibels.

The conditioning means may comprise a 3D capacitor situated laterally to the prior art pad.

Note that with the pad in FIG. 2, the losses are more limited than with the prior art pad and lateral conditioning means. The parasitic capacitance is thus lower for the pad in FIG. 2 than for the ensemble constituted by the prior art pad and the lateral 3D capacitor.

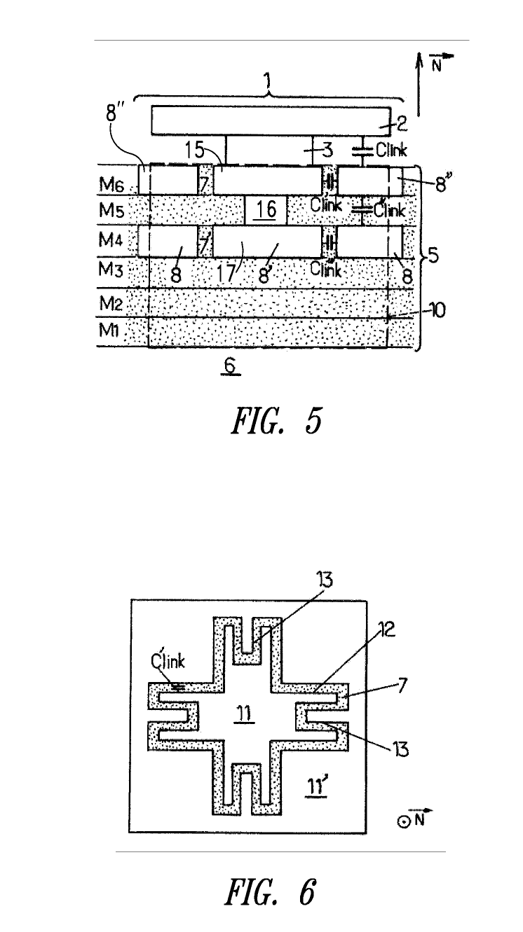

FIG. 5 shows an example of a bonding pad in another embodiment of the invention.

This pad 1 comprises an encapsulation layer 2 covering a portion 10 of a stack 5 of conductive layers M1, . . . , M6. The pad 1 comprises several conductive areas 8, 8′, 8″. The conductive area 8′ is in electrical contact with the encapsulation layer 2 via a contact layer 3. The areas 8, 8″ are insulated from the encapsulation layer 2.

The layer M6 comprises, for the portion 10 corresponding to the pad, the conductive area 8″ and a first portion 15 of the conductive area 8′, where the area 8″ surrounds the first portion 15 in said layer M6. The dielectric area 7 of the layer M6 insulates the first portion 15 of the conductive area 8′ from the conductive area 8″. The layer M5 comprises, for the portion 10 corresponding to the pad, a second portion 16 of the conductive area 8′. The layer M4 comprises, for the portion 10 corresponding to the pad, the conductive area 8 and a third portion 17 of the conductive area 8′ where the area 8 surrounds the third portion 17 in said layer M4. A dielectric area 7′ of the layer M4 insulates the third portion 17 of the conductive area 8′ from the conductive area 8.

The signals received by the encapsulation layer 2 travel through the area 8 for delivery to the circuit core 400, not represented in FIG. 5. Due to the capacitances Cₗᵢₙₖ, Cₗᵢₙₖ′, Cₗᵢₙₖ″, Cₗᵢₙₖ′″ obtained because of this distribution of the conductive areas, the signals traveling to the circuit core may be decoupled in a relatively efficient manner.

The capacitances Cₗᵢₙₖ, Cₗᵢₙₖ″, or interlayer capacitances, are obtained due to the separations between the metal areas 8, 8″ from one layer to another and between the metal area 8″ of the layer M6 and the encapsulation layer 2, respectively.

The capacitances Cₗᵢₙₖ′, Cₗᵢₙₖ′″, or intralayer capacitances, are obtained due to the coexistence in the same layer M6, M4 of plural conductive areas separated by the insulating areas 7, 7′.

FIG. 6 is a top-down view of a conductive layer in an example of a pad according to an embodiment of the invention, for example layer M6 or M4.

In this example, this layer comprises, for the portion corresponding to the pad, two conductive areas 11, 11′ where one surrounds the other. These areas have projecting teeth 12, 13, which interleave with each other. Thus relatively large surface areas are facing each other, which allows a relatively high intralayer capacitance Cₗᵢₙₖ′.

Of course, the conductive areas in the same layer and in the portion corresponding to the pad may have other forms, such as interleaved combs comprising a certain number of teeth, for example a dozen to several dozen.

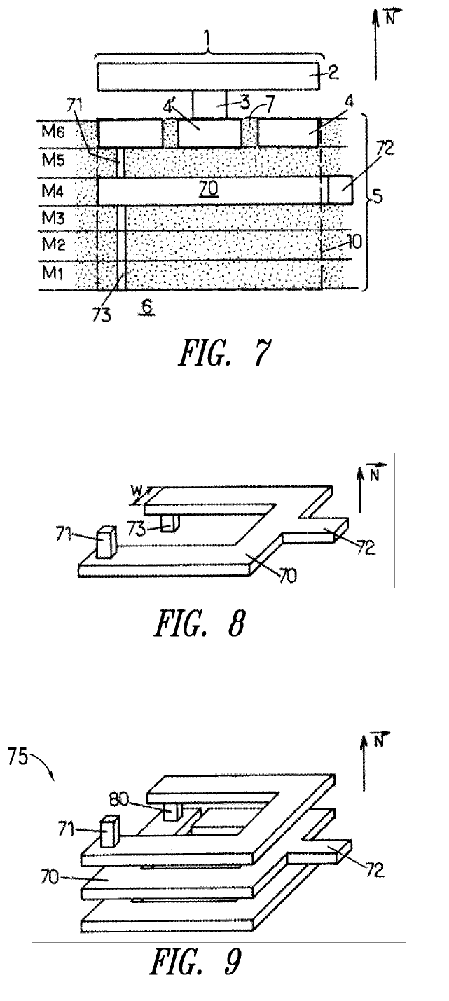

FIG. 7 shows a diagram of an example of a bonding pad in an embodiment of the invention. FIG. 8 is a perspective view of a conductive area 70 of the bonding pad of FIG. 7, with the rest of the pad not represented in the figure. These two figures will be discussed together.

An electrical bonding pad 1 realized in a stack 5 of conductive layers M1, . . . , M6, comprises an encapsulation layer 2, for example a layer of AluCap™ realized of aluminum. This encapsulation layer 2 covers a portion 10, delimited by dotted lines in FIG. 7, of the stack 5 of conductive layers M1, . . . , M6.

The pad comprises two conductive areas 4, 4′ in the same conductive layer M6. The area 4 surrounds the area 4′, and these areas 4, 4′ are separated from each other by an insulating area 7.

The encapsulation layer 2 is in electrical contact with the area 4′ via the contact layer 3.

The pad further comprises a conductive area 70 comprising an area input 71, here a via, and an area output 72 for delivering the signals received by the pad to the circuit core, not represented in FIG. 7. The area 70 is elongated between the area input 71 and the area output 72, so as to ensure frequency filtering of the signals traveling through the area 70.

In this example, the area 70 is not rectilinear between the area input 71 and the area output 72. The area 70 forms, between the area input 71 and the area output 72, a spiral of ⅜ths of a turn in the layer M4. The area 70 thus forms the start of a coil.

In this example, the elongated area 70 extends beyond the area output 72, to a virtual ground 73 connected to a ground not represented. The area 70 as a whole thus forms a spiral of ¾ths of a turn. The area output 72 is located between the area input 71 and the virtual ground 73. The pad 1 thus integrates a transformer, without adding to the space required.

The width w of the elongated area 70 is chosen to ensure impedance matching according to techniques well known to a person skilled in the art. The pad 1 thus allows realizing impedance matching without increasing the space required.

The invention is not limited to a decoupling inside the pad. For example, the conductive areas handling the transfer of received signals to the circuit core may all be in electrical contact with the encapsulation layer 2.

FIG. 9 is a perspective view of a conductive area of a bonding pad according to an embodiment of the invention, with the rest of the pad not represented in the figure.

In this example, a conductive area 75 of a bonding pad includes the elongated area 70, the area input 71, the area output 72, and a virtual ground (not visible in FIG. 9). The conductive area 75 extends in a spiral of several turns to form a coil through several layers not represented in FIG. 9. Each turn of the spiral corresponds to a conductive layer, and vias 80 provide passage from one layer to another. The area output 72 is located in the elongated area between the area input 71 and the virtual ground, such that the conductive area 75 may serve as a transformer.

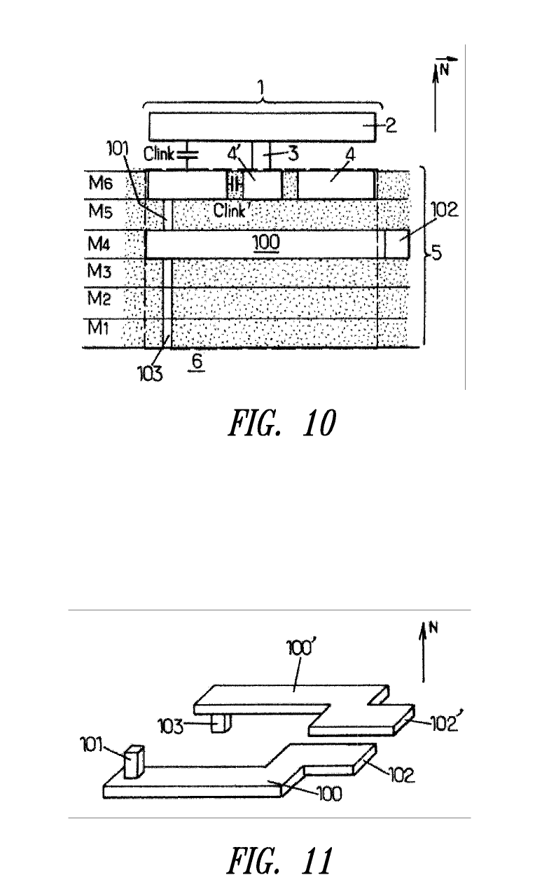

FIG. 10 schematically shows an example of a bonding pad which integrates a balun, according to an embodiment of the invention. FIG. 11 is a perspective view of two conductive areas 100, 100′ of the bonding pad of FIG. 10, with the rest of the pad not represented in the figure. These figures will be discussed together.

The bonding pad 1 of FIG. 10 is realized in a stack of conductive layers M1, . . . , M6. This pad 1 comprises an encapsulation layer 2 and conductive areas 4, 4′, 100, 100′ for ensuring the passage towards the circuit core 400, not represented in FIG. 10, of signals received by the encapsulation layer 2.

The areas 4, 4′ are arranged in the layer M6 to ensure a decoupling of the signals received, here through the interlayer capacitance Cₗᵢₙₖ and intralayer capacitance Cₗᵢₙₖ′.

The layer M4 contains the major part of the areas 100 and 100′, which are more visible in FIG. 11. The area 100 comprises an area input 101 in contact with the conductive area 4, and an area output 102 for delivering to the circuit core the signals received from the conductive area 4. The area 100 is elongated between said area input 101 and said area output 102. The area 100′ comprises a supplemental area output 102′ and a virtual ground 103. The area 100′ is elongated between said supplemental area output 102′ and said virtual ground 103.

These areas 100, 100′ allow balancing the signals received by the pad 1. The pad 1 thus integrates a balun which allows eliminating the even components of the electrical signal traveling through the pad, particularly the direct component.

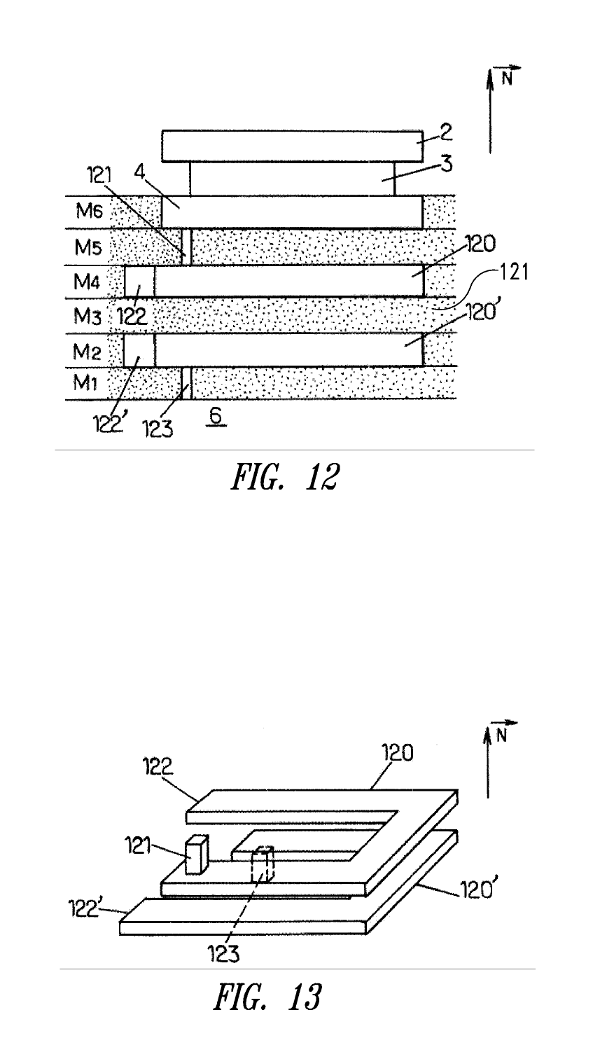

FIGS. 12 and 13 show another embodiment of the invention.

The pad 1 comprises the conductive area 4, in contact with the encapsulation layer 2 via a contact layer 3. The conductive area 120 is in contact with the area 4 by a via 121. As represented in FIG. 13, this area 120 extends from the via 121 to an area output 122 intended for delivering signals received by the pad to a circuit core, not represented.

An area 120′, insulated from the area 120 by a dielectric area 121 of the conductive layer M3, extends between a supplemental area output 122′ intended to be attached to the circuit core, and a virtual ground 123.

The pad 1 thus integrates a balun.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A bonding pad for an integrated electronic circuit, comprising:
an encapsulation layer for receiving electrical signals; and
a stack of conductive layers including a first conductive area at least partially covered by the encapsulation layer,
wherein said first conductive area is configured to pass to a circuit core electrical signals received by the encapsulation layer, and is electrically insulated from the encapsulation layer so as to at least partially decouple the electrical signals received from the encapsulation layer,
wherein at least one of the conductive layers of the stack comprises:
the first conductive area;
a second conductive area at least partially covered by the encapsulation layer, and
a first insulating area insulating the first and second conductive areas from each other, the first insulating area being at least partially covered by the encapsulation layer.

2. The bonding pad according to claim 1 wherein inside a portion of the stack covered by the encapsulation layer the layers of the stack include a conductive layer, farthest from the encapsulation layer and into which a conductive area at least partially extends, further comprises an insulating area.

3. The bonding pad according to claim 1 wherein one of the conductive areas surrounds the other.

4. The bonding pad according to claim 1 wherein the stack includes a second insulating area underlying the first conductive area and a third conductive area underlying the second insulated area, the second insulating area insulating the first and third conductive areas from each other and being at least partially covered by the encapsulation layer.

5. The bonding pad according to claim 4 wherein the stack includes:
a fourth conductive area underlying the second conductive area;
a third insulating area that insulates the third conductive area from the fourth conductive area; and
a fifth conductive area positioned between and electrically connecting the second and fourth conductive areas.

6. The bonding pad according to claim 1, further comprising a conductive contact layer positioned on the stack and electrically connecting the second conductive area to the encapsulation layer.

7. The bonding pad according to claim 1 wherein the stack includes:
an electrical connector underlying and contacting the first conductive area; and
an elongated third conductive area connected to the first conductive area by the electrical connector, the third conductive area underlying the first and second conductive areas and being configured to be coupled to the circuit core.

8. The bonding pad according to claim 1 wherein the stack includes:
a spiral conductive area electrically connected to the first conductive area and at least partially underlying the encapsulation layer.

9. The bonding pad according to claim 1 wherein the stack includes:
a balun having first and second elongated conductive areas positioned in the same one of the conductive layers and spaced apart from each other, the first elongated conductive area including an input connector connected to the first conductive area and a first output area configured to be coupled to the core circuit, and the second elongated conductive area including a virtual ground portion and a second output area configured to be coupled to the core circuit.

10. The bonding pad according to claim 1 wherein the stack includes:
a second conductive area electrically coupled to the encapsulation layer; and
an insulating area underlying the second conductive area and overlying the first conductive area, the insulating area insulating the second conductive area from the first conductive area.

11. An integrated electronic circuit, comprising:
a circuit core; and
a bonding pad that includes:
an encapsulation layer for receiving electrical signals; and
a stack of conductive layers including a first conductive area at least partially covered by the encapsulation layer, wherein said first conductive area is configured to pass to the circuit core the electrical signals received by the encapsulation layer, and is electrically insulated from the encapsulation layer so as to at least partially decouple the electrical signals received from the encapsulation layer, wherein at least one of the conductive layers of the stack comprises:
the first conductive area;
a second conductive area at least partially covered by the encapsulation layer, and
a first insulating area insulating the first and second conductive areas from each other, the first insulating area being at least partially covered by the encapsulation layer.

12. The integrated circuit according to claim 11 wherein inside a portion of the stack covered by the encapsulation layer the layers of the stack include a conductive layer, farthest from the encapsulation layer and into which a conductive area at least partially extends, further comprises an insulating area.

13. The integrated circuit according to claim 11 wherein one of the conductive areas surrounds the other.

14. The integrated circuit according to claim 11 wherein the stack includes a second insulating area underlying the first conductive area and a third conductive area underlying the second insulated area, the second insulating area insulating the first and third conductive areas from each other and being at least partially covered by the encapsulation layer.

15. The integrated circuit according to claim 14 wherein the stack includes:
a fourth conductive area underlying the second conductive area;
a third insulating area that insulates the third conductive area from the fourth conductive area; and
a fifth conductive area positioned between and electrically connecting the second and fourth conductive areas.

16. The integrated circuit according to claim 11, wherein the bonding pad includes a conductive contact layer positioned on the stack and electrically connecting the second conductive area to the encapsulation layer.

17. The integrated circuit according to claim 11 wherein the stack includes:
an electrical connector underlying and contacting the first conductive area; and
an elongated third conductive area connected to the first conductive area by the electrical connector, the third conductive area underlying the first and second conductive areas and being configured to be coupled to the circuit core.

18. A method for manufacturing a bonding pad for an integrated electronic circuit, comprising
creating a conductive area in a stack of conductive layers,
creating an encapsulation layer at least partially covering the conductive area, the encapsulation layer being separated from the conducting area by an insulating area so as to at least partially ensure a decoupling of electrical signals received by the encapsulation layer and traveling through the conductive area for delivery to a circuit core, wherein at least one of the conductive layers of the stack comprises:
the first conductive area;
a second conductive area at least partially covered by the encapsulation layer, and
a first insulating area insulating the first and second conductive areas from each other, the first insulating area being at least partially covered by the encapsulation layer.

19. An integrated electronic circuit, comprising
a circuit core; and
an electrical bonding pad that includes:
an encapsulation layer for receiving electrical signals;
a stack of conductive layers that includes a conductive area, said conductive area being at least partially covered by the encapsulation layer, wherein said conductive area comprises an area input, an area output for the passage of electrical signals received by the encapsulation layer and traveling to the circuit core, wherein said conductive area includes a balun and is elongated between the area input and the area output so as to ensure frequency filtering of the electrical signals traveling through said conductive area.

20. The integrated circuit according to claim 20, wherein the elongated conductive area extends so as to form a spiral of more than a quarter turn.

21. A method for manufacturing a bonding pad for an integrated electronic circuit, comprising:
creating a conductive area in a stack of conductive layers, said conductive area comprising an area input and an area output for the passage of signals received by the pad and traveling to a circuit core, said conductive area including a balun and being elongated between said area input and said area output so as to ensure frequency filtering of the electrical signals traveling through said conductive area; and
creating an encapsulation layer for receiving and sending electrical signals to the conductive area, said encapsulation layer at least partially covering the conductive area.
